(19) United States
(12) Patent Application Publication
(10) Pub. No.: US 2022/0301870 A1
(43) Pub. Date: Sep. 22, 2022

(54) SEMICONDUCTOR MANUFACTURING METHOD AND SEMICONDUCTOR MANUFACTURING APPARATUS

(71) Applicant: Kioxia Corporation, Tokyo (JP)

(72) Inventors: Atsushi FUKUMOTO, Kuwana (JP); Fumiki AISO, Kuwana (JP)

(73) Assignee: Kioxia Corporation, Tokyo (JP)

(21) Appl. No.: 17/474,929

(22) Filed: Sep. 14, 2021

(30) Foreign Application Priority Data
Mar. 18, 2021 (JP) 2021-044822

(51) Int. Cl. H01L 21/02; H01L 27/11582; C30B 1/10; C30B 29/06; C23C 16/24; C23C 16/02; C23C 16/56

(52) U.S. Cl. CPC H01L 21/02669; H01L 27/11582; H01L 21/02592; H01L 21/02532; H01L 21/0262; H01L 21/02645; C30B 1/10; C30B 29/06; C23C 16/24; C23C 16/0272; C23C 16/56

(57) ABSTRACT

According to an embodiment, a semiconductor manufacturing method includes forming a first seed layer on an underlying layer with a first gas that is an aminosilane gas. The method further includes forming a first amorphous silicon layer on the first seed layer with a second gas that is a silane gas not containing an amino group. The method further includes forming a second seed layer containing impurities on the first amorphous silicon layer with a third gas that is an aminosilane gas. The method further includes forming a second amorphous silicon layer on the second seed layer with a fourth gas that is a silane gas not containing an amino group.

### CROSS REFERENCE TO RELATED APPLICATIONS

This application is based upon and claims the benefit of priority from the prior Japanese Patent Application No. 2021-44822, filed on Mar. 18, 2021, the entire contents of which are incorporated herein by reference.

### FIELD

Embodiments of the present invention relate to a semiconductor manufacturing method and a semiconductor manufacturing apparatus.

### BACKGROUND

In manufacturing a semiconductor storage device, when amorphous silicon in a memory hole is crystallized to monocrystalline silicon by MILC (Metal-induced Lateral Crystallization), the crystallization to monocrystalline silicon is inhibited by crystallization to polycrystalline silicon in some cases.

### BRIEF DESCRIPTION OF THE DRAWINGS

FIG. 1 is a diagram illustrating a semiconductor manufacturing apparatus according to a first embodiment;

FIG. 2 is a flowchart illustrating a semiconductor manufacturing method according to the first embodiment;

FIG. 3 is a cross-sectional view illustrating the semiconductor manufacturing method according to the first embodiment;

FIG. 4 is a cross-sectional view illustrating the semiconductor manufacturing method according to the first embodiment in continuation from FIG. 3;

FIG. 5 is a cross-sectional view illustrating the semiconductor manufacturing method according to the first embodiment in continuation from FIG. 4;

FIG. 6 is a cross-sectional view illustrating the semiconductor manufacturing method according to the first embodiment in continuation from FIG. 5;

FIG. 7 is a cross-sectional view illustrating the semiconductor manufacturing method according to the first embodiment in continuation from FIG. 6;

FIG. 8 is a cross-sectional view illustrating the semiconductor manufacturing method according to the first embodiment in continuation from FIG. 7;

FIG. 9 is a cross-sectional view illustrating the semiconductor manufacturing method according to the first embodiment in continuation from FIG. 8;

FIG. 10 is a cross-sectional view illustrating the semiconductor manufacturing method according to the first embodiment in continuation from FIG. 9;

FIG. 11 is a cross-sectional view illustrating the semiconductor manufacturing method according to the first embodiment in continuation from FIG. 10;

FIG. 12 is a diagram illustrating a semiconductor manufacturing apparatus according to a second embodiment; and

FIG. 13 is a diagram illustrating a semiconductor manufacturing apparatus according to a third embodiment.

### DETAILED DESCRIPTION

According to an embodiment, a semiconductor manufacturing method includes forming a first seed layer on an underlying layer with a first gas that is an aminosilane gas. The method further includes forming a first amorphous silicon layer on the first seed layer with a second gas that is a silane gas not containing an amino group. The method further includes forming a second seed layer containing impurities on the first amorphous silicon layer with a third gas that is an aminosilane gas. The method further includes forming a second amorphous silicon layer on the second seed layer with a fourth gas that is a silane gas not containing an amino group.

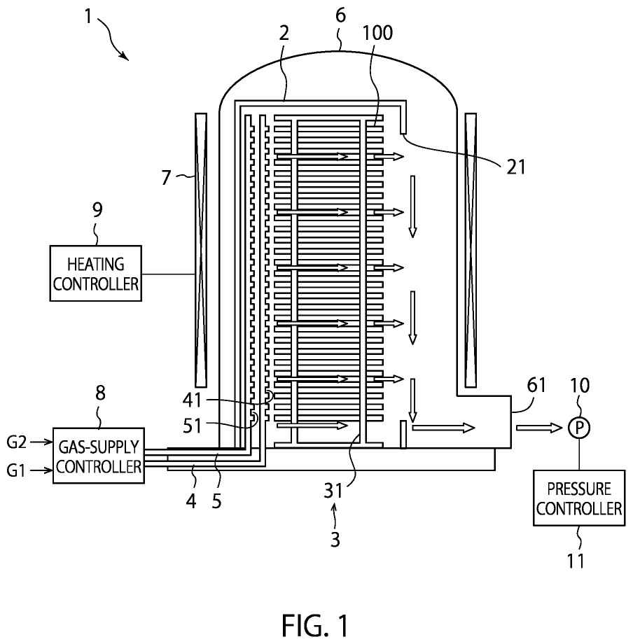

Embodiments of the present invention will be explained below with reference to the drawings. In FIGS. 1 to 13, same or identical constituent elements are denoted by like reference characters and redundant explanations thereof are omitted.

### First Embodiment

FIG. 1 is a diagram illustrating a semiconductor manufacturing apparatus 1 according to a first embodiment. As illustrated in FIG. 1, the semiconductor manufacturing apparatus 1 according to the first embodiment includes a processing chamber 2, a boat 3, a first gas supply tube 4, a second gas supply tube 5, a cover member 6, a heating device 7, a gas-supply controller 8, a heating controller 9, a pump 10, and a pressure controller 11.

The processing chamber 2 is a hollow structure that can accommodate a plurality of semiconductor substrates 100. The processing chamber 2 is provided with an exhaust port 21 through which an exhaust gas that has processed the semiconductor substrates 100 is exhausted. For example, the exhaust port 21 is formed by a long hole extending in the vertical direction, and the exhaust port 21 has a constant width in a direction perpendicular to the vertical direction.

The boat 3 is arranged in the processing chamber 2. The boat 3 has a support 31 that extends in the vertical direction. The support 31 is provided with a plurality of horizontal grooves (not illustrated) arranged at an interval in the vertical direction. By insertion of the semiconductor substrates 100 into the respective grooves, the boat 3 can hold the semiconductor substrates 100 while the semiconductor substrates 100 are stacked at an interval in the vertical direction (that is, in the thickness direction of the semiconductor substrate 100).

The first gas supply tube 4 is arranged in the processing chamber 2. The first gas supply tube 4 is a tube for supplying a first gas G1 that is an aminosilane gas to the semiconductor substrates 100. Specifically, the first gas supply tube 4 extends in the vertical direction to face the boat 3 from the side. The first gas supply tube 4 is provided with a plurality of first discharge ports 41 that discharge the first gas G1 towards the semiconductor substrates 100 held by the boat 3. The first discharge ports 41 are provided for the respective semiconductor substrates 100 in a one-to-one positional relation. For example, the same number of the first discharge ports 41 as the number of the semiconductor substrates 100 held by the boat 3 are provided, and the position in the vertical direction, that is, the height of each first discharge port 41 and the semiconductor substrate 100 corresponding thereto substantially match each other. The first discharge ports 41 have, for example, a constant cross-sectional area. Since the first discharge ports 41 are provided for the respective semiconductor substrates 100 in a one-to-one positional relation, the thicknesses of a first seed layer 108 and a second seed layer 110, which will be described later, can be made uniform between the semiconductor substrates 100. Although the number of the first gas supply tubes 4 is one in the example illustrated in FIG. 1, a plurality of the first gas supply tubes 4 may be arranged in the processing chamber 2.

As the first gas G1 that is an aminosilane gas, a gas containing at least one aminosilane can be suitably used which is selected from a group of butylaminosilane, bis(tert-butylamino)silane, dimethylaminosilane, bis(dimethylamino)silane, tris(dimethylamino)silane, diethylaminosilane, bis(diethylamino)silane, dipropylaminosilane, and diisopropylaminosilane, for example.

The second gas supply tube 5 is arranged in the processing chamber 2. The second gas supply tube 5 is a tube for supplying a second gas G2 that is a silane gas not containing an amino group to the semiconductor substrates 100. Specifically, the second gas supply tube 5 extends in the vertical direction to face the boat 3 from the side. The second gas supply tube 5 is provided with a plurality of second discharge ports 51 that discharge the second gas G2 that is a silane gas not containing an amino group towards the semiconductor substrates 100 held by the boat 3. The second discharge ports 51 have, for example, a constant cross-sectional area. Although the number of the second gas supply tubes 5 is one in the example illustrated in FIG. 1, a plurality of the second gas supply tubes 5 may be arranged in the processing chamber 2.

As the second gas G2 that is a silane gas not containing an amino group, a gas containing at least one silane can be suitably used which is selected from a group of SiH₂, SiH₄, SiH₆, Si₂H₄, Si₂H₆, silicon hydride represented by SiₘH₂ₘ₊₂ (where m is a natural number of 3 or more), and silicon hydride represented by SinH₂ₙ (where n is a natural number of 3 or more), for example.

The cover member 6 is arranged outside the processing chamber 2 to cover the processing chamber 2. The cover member 6 is provided with an exhaust port 61. An exhaust gas exhausted through the exhaust port 21 of the processing chamber 2 is exhausted to outside through the exhaust port 61.

The heating device 7 is arranged outside the cover member 6 to surround the cover member 6. The heating device 7 heats the processing chamber 2 from the outside of the cover member 6 to activate the gases G1 and G2 supplied into the processing chamber 2 and to heat the semiconductor substrates 100.

The gas-supply controller 8 controls supply of the first gas G1 by the first gas supply tube 4. Specifically, the gas-supply controller 8 controls whether to cause the first gas G1 to flow from a gas source of the first gas G1 to the first gas supply tube 4 and also controls the flow rate. Further, the gas-supply controller 8 controls supply of the second gas G2 by the second gas supply tube 5. Specifically, the gas-supply controller 8 controls whether to cause the second gas G2 to flow from a gas source of the second gas G2 to the second gas supply tube 5 and also controls the flow rate. The gas-supply controller 8 may include, for example, a mass flow controller and a solenoid valve.

The heating controller 9 controls heating by the heating device 7, thereby controlling the temperature in the processing chamber 2, that is, a processing temperature of the semiconductor substrates 100.

The pump 10 is arranged at a downstream position in a gas flow with respect to the exhaust port 61. The pump 10 exhausts air in the processing chamber 2, thereby exhausting an exhaust gas that has processed the semiconductor substrates 100 from the processing chamber 2.

The pressure controller 11 controls the exhaust by the pump 10 to control the pressure in the processing chamber 2, that is, a processing pressure of the semiconductor substrates 100.

Next, a semiconductor manufacturing method according to the first embodiment is described in which the semiconductor manufacturing apparatus 1 configured in the above-described manner is applied.

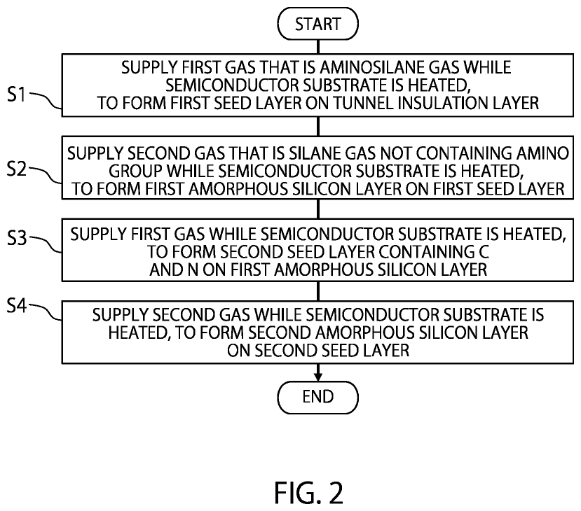

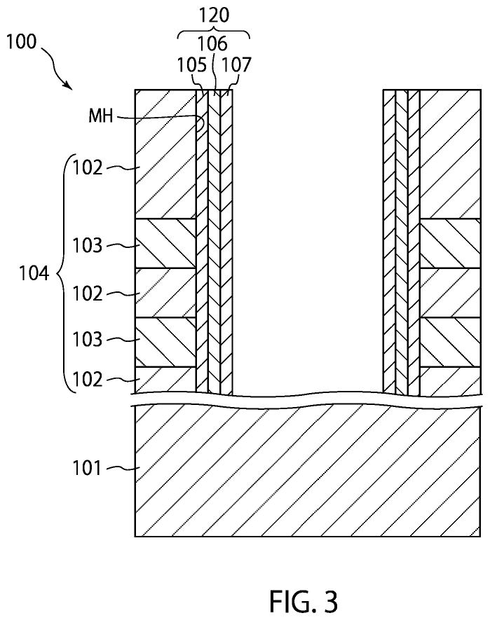

FIG. 2 is a flowchart illustrating the semiconductor manufacturing method according to the first embodiment. FIG. 3 is a cross-sectional view illustrating the semiconductor manufacturing method according to the first embodiment.

The semiconductor manufacturing method according to the first embodiment includes processes of deposition by heat treatment in accordance with the flowchart in FIG. 2. At least the deposition processes in FIG. 2 are carried out by the semiconductor manufacturing apparatus 1 described above. As an initial state in FIG. 2, the structure illustrated in FIG. 3 has been formed on each semiconductor substrate 100 by a previous process of FIG. 2. As illustrated in FIG. 3, each semiconductor substrate 100 includes a stacked body 104 and a memory film 120 above a silicon substrate 101 in the initial state in FIG. 2. The stacked body 104 is a structure in which an insulation layer 102 made of, for example, silicon oxide and a sacrifice layer 103 made of, for example, silicon nitride are stacked alternately. The memory film 120 is provided along the sidewall of a memory hole MH that penetrates through the stacked body 104 in a stacking direction. The memory film 120 includes a block insulation layer 105, a charge storage layer 106, and a tunnel insulation layer 107 from outside (that is, the side close to the sidewall of the memory hole MH) in that order. The block insulation layer 105 and the tunnel insulation layer 107 are made of, for example, silicon oxide. The charge storage layer 106 is made of, for example, silicon nitride.

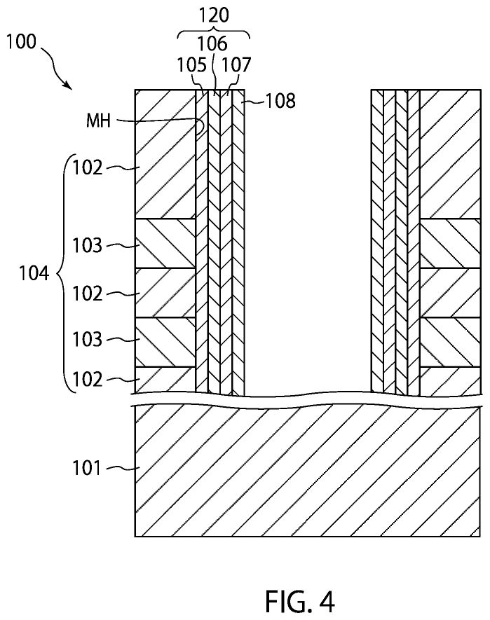

FIG. 4 is a cross-sectional view illustrating the semiconductor manufacturing method according to the first embodiment in continuation from FIG. 3. From the initial state illustrated in FIG. 3, as illustrated in FIG. 2, the first gas G1 that is an aminosilane gas is supplied to the semiconductor substrate 100 while the semiconductor substrate 100 is heated. At this time, it is preferable that the heating controller 9 controls the temperature in the processing chamber 2 to be 325° C. or higher and 450° C. or lower. Further, it is preferable that the pressure controller 11 controls the pressure in the processing chamber 2 to be 27 Pa or higher and 1000 Pa or lower. It is preferable that as the deposition temperature is lower, the pressure is higher. As illustrated in FIG. 4, by supplying the first gas G1 to the semiconductor substrate 100 while the semiconductor substrate 100 is heated, the first seed layer 108 is formed on the tunnel insulation layer 107 (that is, on the inside of the tunnel insulation layer 107). The first seed layer 108 is a layer that causes silicon nuclei to be formed uniformly on the tunnel insulation layer 107 as an underlying layer to realize easy adsorption of monosilane. A silane gas not containing an amino group (for example, Si₂H₆) may be further used in formation of the first seed layer 108.

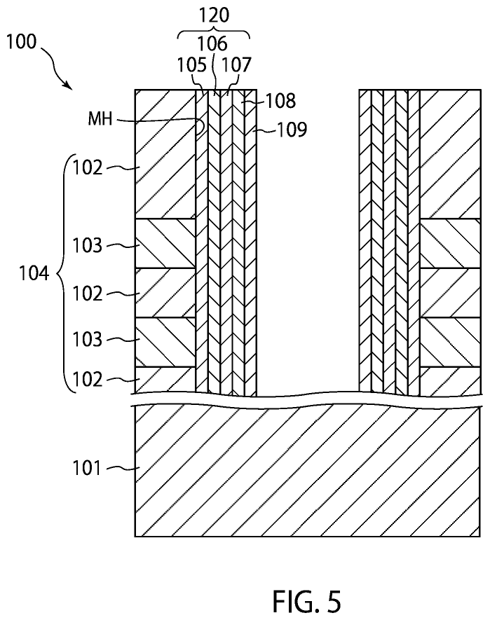

FIG. 5 is a cross-sectional view illustrating the semiconductor manufacturing method according to the first embodiment in continuation from FIG. 4. As illustrated in FIG. 2, after the first seed layer 108 is formed, the second gas G2 that is a silane gas not containing an amino group is supplied to the semiconductor substrate 100 while the semiconductor substrate 100 is heated. At this time, it is preferable that the heating controller 9 controls the temperature in the processing chamber 2 to be higher than the temperature during formation of the first seed layer 108. The temperature in the processing chamber 2 is more preferably 450° C. or higher and 550° C. or lower. It suffices that the pressure in the processing chamber 2 is the same level as the pressure during formation of the first seed layer 108. As illustrated in FIG. 5, by supplying the second gas G2 to the semiconductor substrate 100 while the semiconductor substrate 100 is heated, a first amorphous silicon layer 109 is formed on the first seed layer 108 (that is, on the inside of the first seed layer 108).

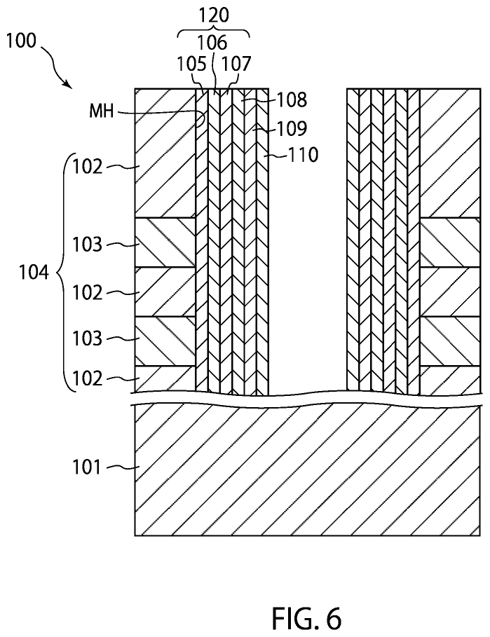

FIG. 6 is a cross-sectional view illustrating the semiconductor manufacturing method according to the first embodiment in continuation from FIG. 5. As illustrated in FIG. 2, after the first amorphous silicon layer 109 is formed, the first gas G1 is supplied to the semiconductor substrate 100 while the semiconductor substrate 100 is heated. At this time, it is preferable that the heating controller 9 controls the temperature in the processing chamber 2 to be lower than the temperature during formation of the first amorphous silicon layer 109. The temperature in the processing chamber 2 is more preferably 325° C. or higher and 450° C. or lower. As illustrated in FIG. 6, by supplying the first gas G1 to the semiconductor substrate 100 while the semiconductor substrate 100 is heated, the second seed layer 110 is formed on the first amorphous silicon layer 109 (that is, on the inside of the first amorphous silicon layer 109). The second seed layer 110 is a layer that causes silicon nuclei to be formed uniformly on the first amorphous silicon layer 109 as an underlying layer to realize easy adsorption of monosilane. Unlike the first seed layer 108 formed using the tunnel insulation layer 107 as the underlying layer, the second seed layer 110 is formed using the first amorphous silicon layer 109 as the underlying layer. Therefore, the second seed layer 110 can contain C (carbon) and N (nitrogen) as impurities. The doses of C and N are preferably on the order of 10¹³ atoms/cm². By providing the second seed layer 110, it is possible to inhibit crystallization of amorphous silicon to polycrystalline silicon when MILC described later is carried out.

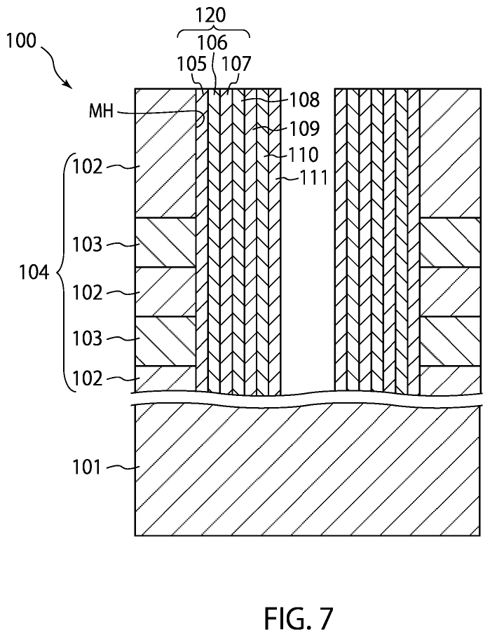

FIG. 7 is a cross-sectional view illustrating the semiconductor manufacturing method according to the first embodiment in continuation from FIG. 6. As illustrated in FIG. 2, after the second seed layer 110 is formed, the second gas G2 is supplied to the semiconductor substrate 100 while the semiconductor substrate 100 is heated. At this time, it is preferable that the heating controller 9 controls the temperature in the processing chamber 2 to be higher than the temperature during formation of the second seed layer 110. The temperature in the processing chamber 2 is more preferably 450° C. or higher and 550° C. or lower. As illustrated in FIG. 7, by supplying the second gas G2 to the semiconductor substrate 100 while the semiconductor substrate 100 is heated, a second amorphous silicon layer 111 is formed on the second seed layer 110 (that is, on the inside of the second seed layer 110). In the following descriptions, a multilayer structure of the first seed layer 108, the first amorphous silicon layer 109, the second seed layer 110, and the second amorphous silicon layer 111 is also referred to as “the amorphous silicon layers 108 to 111”.

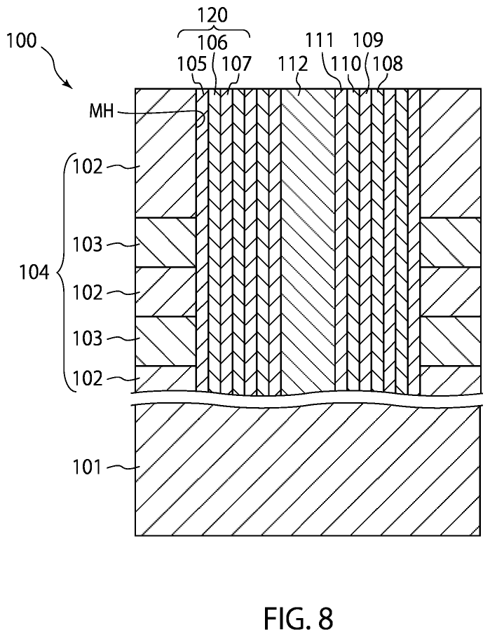

FIG. 8 is a cross-sectional view illustrating the semiconductor manufacturing method according to the first embodiment in continuation from FIG. 7. As illustrated in FIG. 8, after the second amorphous silicon layer 111 is formed, a core layer 112 is formed by, for example, ALD (Atomic Layer Deposition) or CVD (Chemical Vapor Deposition) on the second amorphous silicon layer 111 to be located at the center of the memory hole MH. The core layer 112 is made of, for example, silicon oxide. The core layer 112 is formed at a deposition temperature at which the amorphous silicon layers 108 to 111 are not crystallized to a polycrystalline structure.

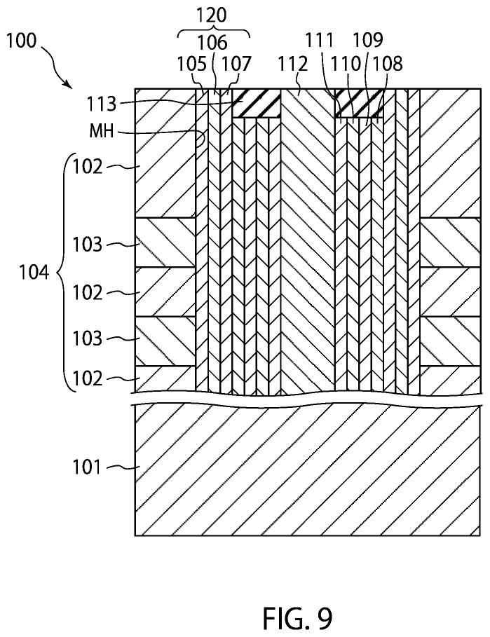

FIG. 9 is a cross-sectional view illustrating the semiconductor manufacturing method according to the first embodiment in continuation from FIG. 8. After the core layer 112 is formed, crystallization of the amorphous silicon layers 108 to 111 to a monocrystalline structure by MILC is carried out. First, as illustrated in FIG. 9, a doped amorphous silicon layer 113 is formed at an upper end of the amorphous silicon layers 108 to 111 by doping, for example, n-type impurities (such as P, As, or B) into the amorphous silicon layers 108 to 111 by ion implantation.

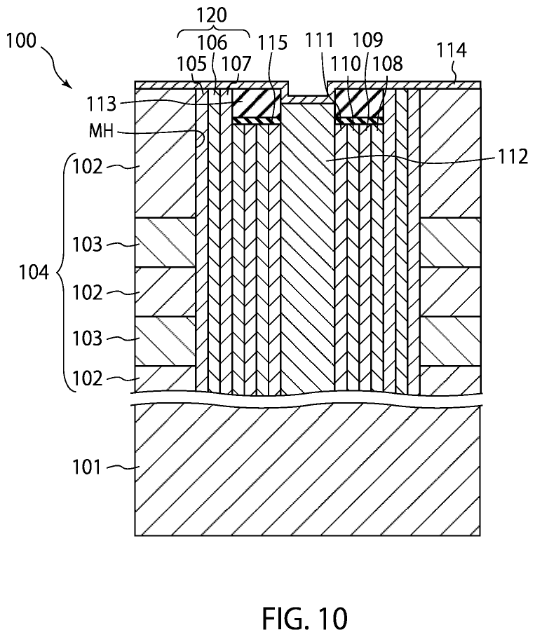

FIG. 10 is a cross-sectional view illustrating the semiconductor manufacturing method according to the first embodiment in continuation from FIG. 9. As illustrated in FIG. 10, after the doped amorphous silicon layer 113 is formed, a metal layer 114 is formed by, for example, PVD (Physical Vapor Deposition) or MO (Metal Organic)-CVD to cover the entire surface of the semiconductor substrate 100. The metal layer 114 contains nickel. It suffices that the metal layer 114 is made of an element that can form silicide, and it may be, for example, Co or Y. After the metal layer 114 is formed, silicide annealing is carried out for the metal layer 114 and the amorphous silicon layers 108 to 111, thereby forming a nickel disilicide layer 115 in upper-end side portions of the amorphous silicon layers 108 to 111.

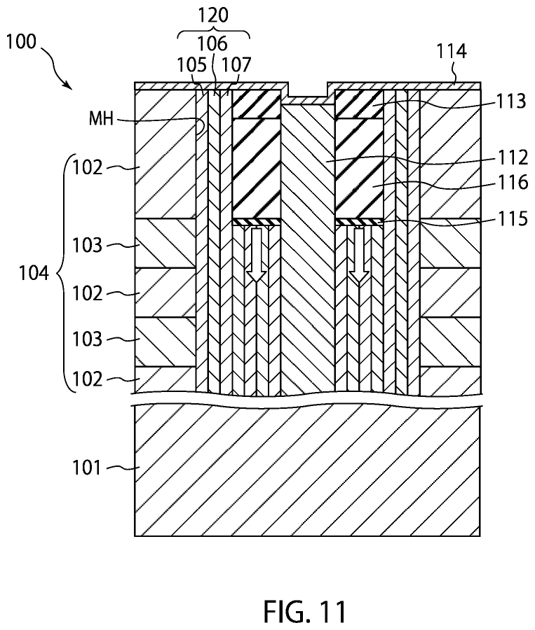

FIG. 11 is a cross-sectional view illustrating the semiconductor manufacturing method according to the first embodiment in continuation from FIG. 10. After the nickel disilicide layer 115 is formed, the amorphous silicon layers 108 to 111 and the nickel disilicide layer 115 are heated at a deposition temperature at which the amorphous silicon layers 108 to 111 are not crystallized to a polycrystalline structure. Accordingly, as illustrated in FIG. 11, crystallization of the amorphous silicon layers 108 to 111 to a monocrystalline structure 116 is performed using the nickel disilicide layer 115 as a catalyst in association with downward migration of the nickel disilicide layer 115. At this time, crystallization of the amorphous silicon layers 108 to 111 to a polycrystalline structure is prevented by the impurities (C and N) in the second seed layer 110, and it is therefore possible to prevent migration of the nickel disilicide layer 115 from being inhibited by the crystallization to a polycrystalline structure.

As described above, according to the first embodiment, it is possible to appropriately crystalize the amorphous silicon layers 108 to 111 to a monocrystalline structure by forming the second seed layer 110 containing impurities between the first amorphous silicon layer 109 and the second amorphous silicon layer 111.

Further, by using the same first gas G1 in formation of the first seed layer 108 and in formation of the second seed layer 110, it is possible to simplify the configuration of the semiconductor manufacturing apparatus 1 and processes. However, the second seed layer 110 may be formed using an aminosilane gas that can contain impurities more easily than the first gas G1. In this case, it is possible to prevent crystallization of the amorphous silicon layers 108 to 111 to a polycrystalline structure more effectively and to crystallize the amorphous silicon layers 108 to 111 to a monocrystalline structure more appropriately.

### Second Embodiment

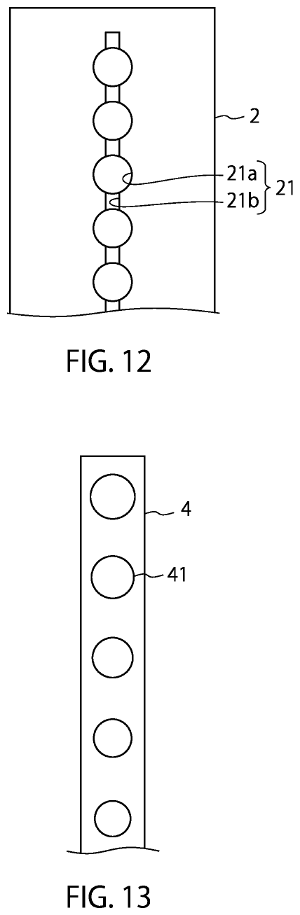

FIG. 12 is a diagram illustrating the semiconductor manufacturing apparatus 1 according to a second embodiment. In the above descriptions, an example of the semiconductor manufacturing apparatus 1 has been described in which the width of the exhaust port 21 is constant. Meanwhile, as illustrated in FIG. 12, in the second embodiment, the cross-sectional area of the exhaust port 21 is larger in a first portion 21a close to the first discharge port 41 (that is, a portion with a height that matches the height of the first discharge port 41) than in a second portion 21b far from the first discharge port 41 (that is, a portion with a height that does not match the height of the first discharge port 41). In the example illustrated in FIG. 12, the first portion 21a is circular. The first portion 21a may be polygonal, for example, rectangular. According to the second embodiment, it is possible to improve the efficiency of exhausting an exhaust gas.

### Third Embodiment

FIG. 13 is a diagram illustrating the semiconductor manufacturing apparatus 1 according to a third embodiment. In the above descriptions, an example of the semiconductor manufacturing apparatus 1 has been described in which the cross-sectional area of the first discharge ports 41 is constant. Meanwhile, in the third embodiment, one of the first discharge ports 41 which is located at a downstream position in the flow of aminosilane gas (an upper position in FIG. 13) has a larger cross-sectional area than one of the first discharge ports 41 which is located on an upstream position in the flow of aminosilane gas (the lower position in FIG. 13). Accordingly, the supply pressures of the first gas G1 to the semiconductor substrates 100 can be made uniform, and therefore the thicknesses of the first seed layer 108 and the second seed layer 110 can be made uniform between the semiconductor substrates 100.

Further, in the third embodiment, the cross-sectional area of the discharge port 21 may be larger in a portion close to the discharge port 41 at the downstream position in the flow of aminosilane gas than in a portion close to the discharge port 41 at the upstream position in the flow of aminosilane gas. This configuration can improve the efficiency of exhausting an exhaust gas.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing method comprising:
forming a first seed layer on an underlying layer with a first gas that is an aminosilane gas;
forming a first amorphous silicon layer on the first seed layer with a second gas that is a silane gas not containing an amino group;
forming a second seed layer containing impurities on the first amorphous silicon layer with a third gas that is an aminosilane gas; and
forming a second amorphous silicon layer on the second seed layer with a fourth gas that is a silane gas not containing an amino group.

2. The method of claim 1, wherein the impurities contain carbon.

3. The method of claim 1, wherein the impurities contain nitrogen.

4. The method of claim 2, wherein the impurities contain nitrogen.

5. The method of claim 1, wherein the underlying layer is a first insulation layer provided along a sidewall of a through hole that penetrates through a stacked body of a first layer and a second layer provided above a substrate.

6. The method of claim 2, wherein the underlying layer is a first insulation layer provided along a sidewall of a through hole that penetrates through a stacked body of a first layer and a second layer provided above a substrate.

7. The method of claim 3, wherein the underlying layer is a first insulation layer provided along a sidewall of a through hole that penetrates through a stacked body of a first layer and a second layer provided above a substrate.

8. The method of claim 5, further comprising:
forming a second insulation layer on the second amorphous silicon layer to be located at a center of the through hole;
forming a silicide layer in upper-end side portions of the first and second amorphous silicon layers; and
crystallizing the first and second amorphous silicon layers to a monocrystalline structure using the silicide layer as a catalyst.

9. The method of claim 8, wherein the silicide layer is a nickel disilicide layer.

10. The method of claim 1, wherein the third gas is same as the first gas.

11. The method of claim 1, wherein the third gas is different from the first gas.

12. The method of claim 1, wherein the fourth gas is same as the second gas.

13. The method of claim 1, wherein the first gas and the third gas are respectively a gas that contains at least one aminosilane selected from a group of butylaminosilane, bis(tert-butylamino)silane, dimethylaminosilane, bis(dimethylamino)silane, tris(dimethylamino)silane, diethylaminosilane, bis(diethylamino)silane, dipropylaminosilane, and diisopropylaminosilane.

14. The method of claim 1, wherein the second gas and the fourth gas are respectively a gas that contains at least one silane selected from a group of SiH₂, SiH₄, SiH₆, Si₂H₄, Si₂H₆, silicon hydride represented by SiₘH₂ₘ₊₂ (where m is a natural number of 3 or more), and silicon hydride represented by SiₙH₂ₙ (where n is a natural number of 3 or more).

15. A semiconductor manufacturing apparatus comprising:
a processing chamber capable of accommodating a plurality of substrates to be processed;
a holder arranged in the processing chamber and being capable of holding the substrates to be processed at an interval in a thickness direction; and
a gas supply tube arranged in the processing chamber and provided with a plurality of discharge ports that discharge an aminosilane gas towards the substrates to be processed held by the holder, wherein
the discharge ports are provided for the respective substrates to be processed in a one-to-one positional relation.

16. The apparatus of claim 15, wherein
the processing chamber is provided with an exhaust port for a gas that has processed the substrates to be processed, along the thickness direction, and
an cross-sectional area of the exhaust port is larger in a portion close to each of the discharge ports than in a portion far from each of the discharge ports.

17. The apparatus of claim 15, wherein a downstream one of the discharge ports in a flow of the aminosilane gas has a larger cross-sectional area than an upstream one of the discharge ports in the flow of the aminosilane gas.

18. The apparatus of claim 16, wherein
a downstream one of the discharge ports in a flow of the aminosilane gas has a larger cross-sectional area than an upstream one of the discharge ports in the flow of the aminosilane gas, and
a cross-sectional area of the exhaust port is larger in a portion close to the downstream one of the discharge ports in the flow of the aminosilane gas than in a portion close to the upstream one of the discharge ports in the flow of the aminosilane gas.

19. The apparatus of claim 15, further comprising a second gas supply tube arranged in the processing chamber and provided with a plurality of second discharge ports that discharge a silane gas not containing an amino group towards the substrates to be processed held by the holder.

20. The apparatus of claim 19, further comprising a controller configured to control supply of the aminosilane gas and the silane gas not containing the amino group towards the substrates to be processed, wherein
the controller is configured to
control supply of the aminosilane gas to each of the substrates to be processed in such a manner that a first seed layer is formed on an underlying layer provided on that substrate,
control supply of the silane gas not containing the amino group to each of the substrates to be processed in such a manner that a first amorphous silicon layer is formed on the first seed layer,
control supply of the aminosilane gas to each of the substrates to be processed in such a manner that a second seed layer containing impurities is formed on the first amorphous silicon layer, and
control supply of the silane gas not containing the amino group to each of the substrates to be processed in such a manner that a second amorphous silicon layer is formed on the second seed layer.
